(19) United States
(12) Patent Application Publication
(10) Pub. No.: US 2005/0118758 A1
(43) Pub. Date: Jun. 2, 2005

(54) Method for arranging layout of CMOS device

(75) Inventors: Feng Yuan, Taipei City (TW); Ching-Fang Huang, Taipei City (TW); Cheewee Liu, Taipei City (TW)

Correspondence Address: ALSTON & BIRD LLP;BANK OF AMERICA PLAZA, 101 SOUTH TRYON STREET, SUITE 4000, CHARLOTTE, NC, 28280-4000, US

(73) Assignee: National Taiwan University

(21) Appl. No.: 10/982,017

(22) Filed: Nov. 5, 2004

(30) Foreign Application Priority Data
Dec. 2, 2003 (TW) 92133791

(51) Int. Cl. H01L 21/8238

(52) U.S. Cl. 438/199

(57) ABSTRACT

A method for arranging a layout of a CMOS (Complementary Metal-Oxide Semiconductor) device is provided. The current direction of the N-type MOS device is perpendicular to the P-type MOS device. The stress along one direction can be applied on both types of MOS devices to enhance the drain current and the operation speed of both devices for CMOS circuit.

### FIELD OF THE INVENTION

The present invention relates to a method for arranging a layout of a CMOS (Complementary Metal-Oxide Semiconductor) device, especially for arranging a layout of a strained CMOSFET (Complementary Metal-Oxide Semiconductor Field Effect Transistor) device.

### BACKGROUND OF THE INVENTION

In the past decade, it has been a common knowledge and technical scheme to fabricate the CMOS (Complementary Metal-Oxide Semiconductor) device in scaling down for increasing the operation speed and the driving current thereof. Based on the ITRS (International Technology Roadmap for Semiconductors) roadmap, such a scheme for raising the operation speed of the CMOS device is almost limitedly developed. As a result, the performance of the CMOS device is hardly improved therethrough.

It is found that the driving current and the operation speed of the CMOS device could be both enhanced by utilizing the strained silicon technology in the CMOS device, due to the enhancement of the carrier mobility. Therefore, compared with the traditional CMOS device with the same gate length, a better performance could be obtained in the CMOS device utilizing the strained silicon technology.

The existing technical schemes for the strained silicon relate to applying a stress on a MOSFET (Metal Oxide Semiconductor Field Effect Transistor). The stress could be applied in two directions, i.e. a horizontal direction and a perpendicular direction, which are defined by the respective directions of the drain current and the applied stress. Please refer to FIGS. 1 and 2, which respectively schematically illustrate the MOSFETs of the horizontal direction type and of the perpendicular direction type. The MOSFET 1 has a source 10, a gate 20 and a drain 30. Both of the horizontal and the perpendicular stresses include the tensile strain and the compressive strain. Through the strained silicon technology, a stress is applied on the channel, which is underneath the gate 20, and the driving current and the operation speed of the MOSFET 1 are enhanced thereby.

In Taiwan Patent Pub. No. 523,818, Mark Armstrong et al. has disclosed a fabrication process for a CMOS device having a PMOS (P-type Metal-Oxide Semiconductor) and an NMOS (N-type Metal-Oxide Semiconductor) which utilizes a special transistor orientation. Based thereon, for no matter a PMOS or an NMOS fabricated on a silicon wafer having an orientation in {100}, a horizontal stress is applied thereon if the MOS has a direction of the drain current passing therethrough in <100>, and a perpendicular stress is applied thereon if the MOS has a direction of the drain current passing therethrough in <110>.

Please refer to FIGS. 3(A) and 3(B), which illustrate the relationship between the applied stress and the carrier mobility in the channel according to the prior art. One can see therefrom that the electron mobility in the channel is enhanced while a tensile strain is applied thereon. However, the hole mobility in the channel is enhanced while a perpendicular tensile strain or a horizontal compressive strain is applied thereon.

Consequently, for simultaneously enhancing the respective carrier mobility of the NMOS and the PMOS, a horizontal tensile strain and a perpendicular tensile strain must be respectively applied thereon.

Hence the present application is to provide a method for the novel layout of the strained CMOS device, which can efficiently enhance the operation speed and the driving current through a simple scheme.

### SUMMARY OF THE INVENTION

In accordance with a first aspect of the present invention, a method for arranging a layout of a CMOS (Complementary Metal-Oxide Semiconductor) device is provided. The method includes steps of providing a silicon substrate, forming an NMOS (N-type Metal-Oxide Semiconductor) and a PMOS (P-type Metal-Oxide Semiconductor) on the silicon substrate to fabricate the CMOS device, and providing a stress source for applying a strain on the NMOS and the PMOS, wherein the direction of the strain on both the NMOS and the PMOS is identical.

Preferably, the NMOS has an NMOS drain current passing therethrough and the PMOS has a PMOS drain current passing therethrough on the silicon substrate, and an angle between a direction of the NMOS drain current and a direction of the PMOS drain current is ranged from 30° to 90°.

Preferably, the direction of the NMOS drain current and the direction of the PMOS drain current are perpendicular to each other.

Preferably, the silicon substrate has an orientation of crystallization of {100}.

Preferably, the direction of the NMOS drain current and the direction of the PMOS drain current are both in a plane having an orientation in <110>.

Preferably, the direction of the NMOS drain current and the direction of the PMOS drain current are both in a plane having an orientation in <100>.

Preferably, the silicon substrate further has one of P-type doping and N-type doping.

Preferably, the strain is one of a tensile strain and a compressive strain.

Preferably, the stress source includes one selected from a group consisting of a high-tensile dielectric of nitrides, a high-compressive dielectric of nitrides, an STI (Shallow Trench Isolation), a strained-silicon layer, a hydrogen ion implantation and an externally mechanical stress source.

Preferably, a plurality of the CMOS devices are fabricated on the silicon substrate.

In accordance with a second aspect of the present invention, a method for arranging a layout of a CMOS (Complementary Metal-Oxide Semiconductor) device is provided. The method includes steps of providing a silicon substrate, providing a stress source for applying a strain on the silicon substrate, and forming an NMOS (N-type Metal-Oxide Semiconductor) and a PMOS (P-type Metal-Oxide Semiconductor) on the silicon substrate to fabricate the CMOS device.

Preferably, the NMOS has an NMOS drain current passing therethrough and the PMOS has a PMOS drain current passing therethrough on the silicon substrate, and an angle between a direction of the NMOS drain current and a direction of the PMOS drain current is ranged from 30° to 90°.

Preferably, the direction of the NMOS drain current and the direction of the PMOS drain current are perpendicular to each other.

Preferably, the silicon substrate has an orientation of crystallization of {100}.

Preferably, the direction of the NMOS drain current and the direction of the PMOS drain current are both in a plane having an orientation in <110>.

Preferably, the direction of the NMOS drain current and the direction of the PMOS drain current are both in a plane having an orientation in <100>.

Preferably, the silicon substrate further has one of P-type doping and N-type doping.

Preferably, the strain is one of a tensile strain and a compressive strain.

Preferably, the stress source includes one selected from a group consisting of a high-tensile dielectric of nitrides, a high-compressive dielectric of nitrides, an STI (Shallow Trench Isolation), a strained-silicon layer, a hydrogen ion implantation and an externally mechanical stress source.

Preferably, a plurality of the CMOS devices are fabricated on the silicon substrate.

In accordance with a third aspect of the present invention, a CMOS devices having a layout formed by the mentioned method is provided.

The foregoing and other features and advantages of the present invention will be more clearly understood through the following descriptions with reference to the drawings, wherein:

### BRIEF DESCRIPTION OF THE DRAWINGS

FIG. 1 is a schematic diagram illustrating the strained MOSFET of the horizontal stress according to the prior art. The I is the direction of the drain current;

FIG. 2 is a schematic diagram illustrating the strained MOSFET of the perpendicular stress according to the prior art. The I is the direction of the drain current;

FIG. 3 is the relationship between the applied stress and the (A) electron (B) hole mobility in the MOS channel according to the prior art;

FIG. 4 is a schematic diagram illustrating a strained CMOS device according to a preferred embodiment of the present invention. The I is the direction of the drain current and the S is the applied stress;

FIG. 5 is a diagram showing the arranged layout of a strained CMOS device according to a preferred embodiment of the present invention;

FIG. 6 is the Hspice simulation plot showing the relationship between the delay time and the carrier mobility enhancement of a ring oscillator having a layout of a strained CMOS device of FIG. 5;

FIG. 7 is a micrograph of a ring oscillator having the CMOS device according to a preferred embodiment of the present invention; and

FIG. 8 is the experiment result showing the relationship between the delay time and the external mechanical strain of the ring oscillator of FIG. 7.

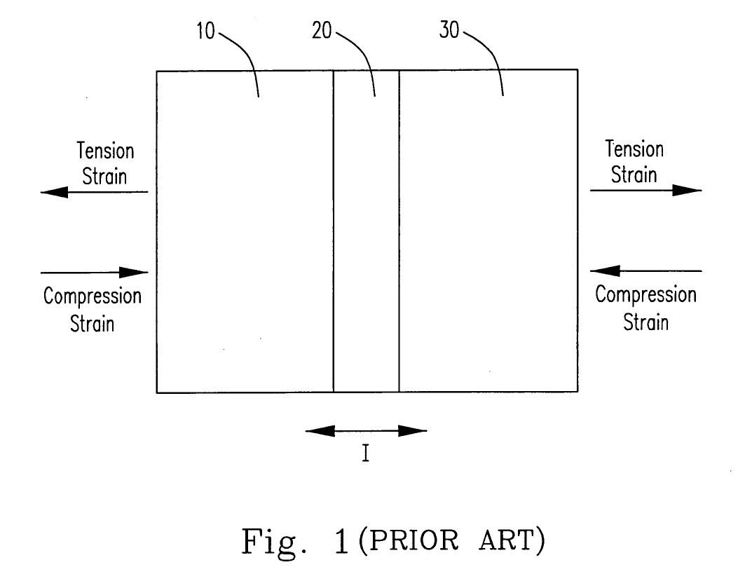

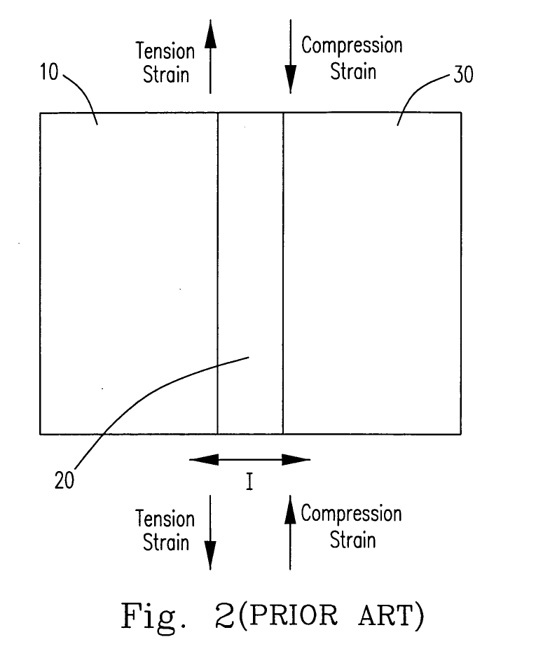

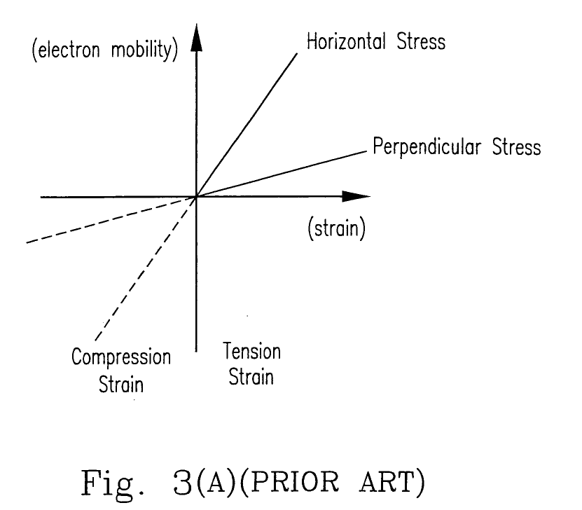

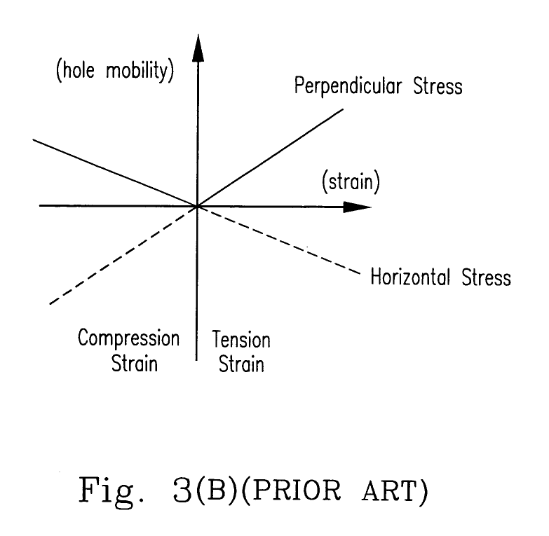

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

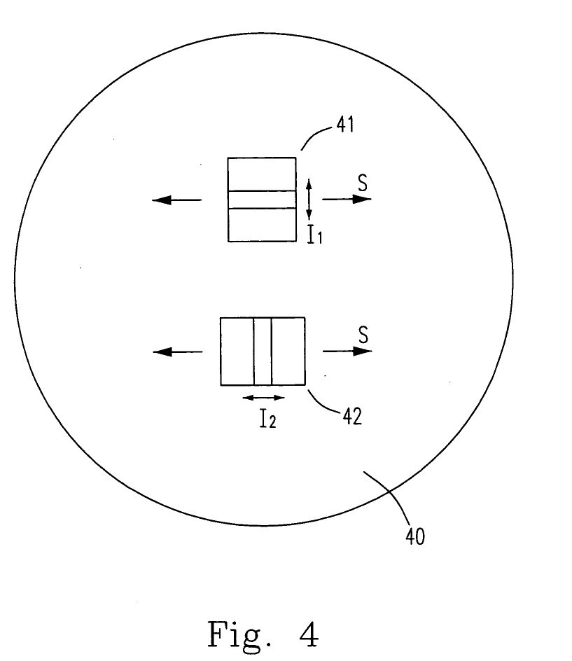

Please refer to FIG. 4, which schematically illustrates the strained CMOS device according to a preferred embodiment of the present invention. A PMOS 41 and an NMOS 42 are formed on a silicon wafer 40, which has an orientation in {100}. The direction of the drain current I₁ which passes through the PMOS 41 is perpendicular to the direction of the drain current I₂ passing through the NMOS 42. Therefore, the applied stress S on the whole silicon wafer 40 is a horizontal stress for the NMOS 42 and is a perpendicular stress for the PMOS 41. Both of the carrier mobilities in the channel of the PMOS and the NMOS are hence increased under the applied tensile stress as a result thereof. In addition, such CMOS devices can be further utilized in a ring oscillator circuit, and the operating speed and the driving current thereof are able to be enhanced.

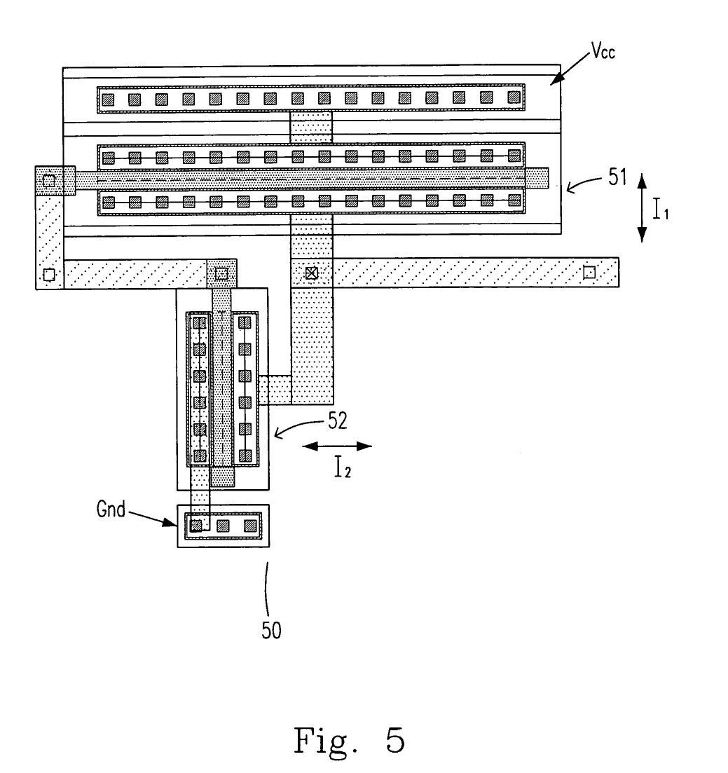

Please refer to FIG. 5, which illustrates the strained CMOS device of FIG. 4 in more detail. The CMOS device 50 has a PMOS 51 and an NMOS 52. The source of a PMOS 51 is electrically connected to the voltage supply Vcc thereof and the source of a NMOS 52 is electrically connected to the power ground Gnd. The direction of the current I₁ passing through the PMOS 51 and the direction of the current I₂ passing through the NMOS 52 are ranged from 30° to 90°, and in this particular case, however, they are perpendicular to each other.

By applying an externally mechanical stress to the whole silicon wafer, a stress of tensile strain has the same direction in respect to the silicon wafer. Since the respective directions of the drain currents passing through the PMOS and the NMOS are perpendicular to each other, the stress of tensile strain will play different roles respectively therefor. For the PMOS, it is a perpendicular tensile strain, and for the NMOS, however, it is a horizontal tensile strain. The respective carrier mobilities in the PMOS and the NMOS are simultaneously enhanced accordingly.

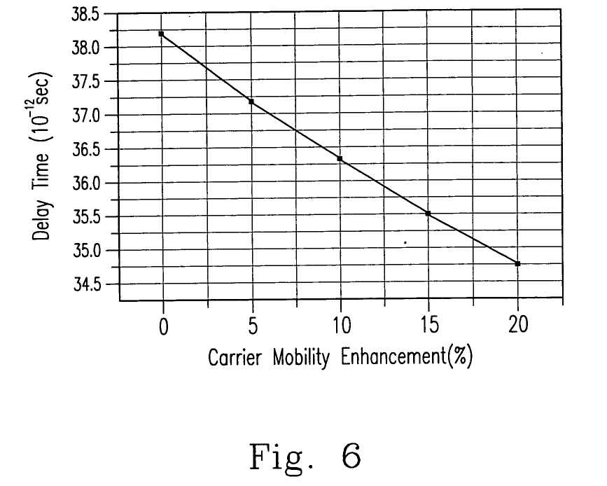

Please refer to FIG. 6 showing the simulation result of the relationship between the delay time and the carrier mobility enhancement of a ring oscillator, which has a layout of strained CMOS device of FIG. 5. One can see therefrom that the delay time of the ring oscillator decreases with the enhancement of the carrier mobility of the PMOS or the NMOS. The operation speed thereof is improved.

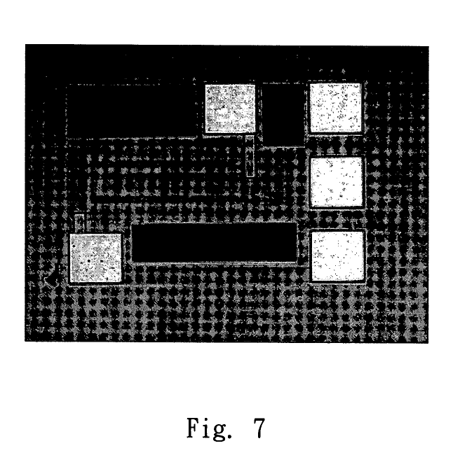

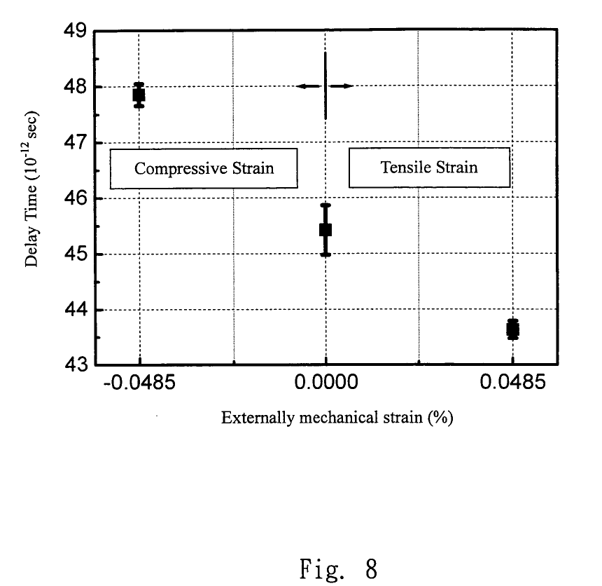

Please refer to FIG. 7 further showing a micrograph of a ring oscillator with 0.25 μm process. The experiment result showing the relationship between the delay time and the external mechanical strain of a ring oscillator is also showed in FIG. 8. The delay time and the operating speed are both enhanced with the layout of strained CMOS device of FIG. 5.

By utilizing the method of the present application, both carrier mobilities of the PMOS and of the NMOS are increased, and the operation speed of the ring oscillator is also improved through a stress applied in the same direction, which is superior to that of the prior art. Therefore, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A method for arranging a layout of a CMOS (Complementary Metal-Oxide Semiconductor) device, comprising the following steps:
providing a silicon substrate;
forming an NMOS (N-type Metal-Oxide Semiconductor) and a PMOS (P-type Metal-Oxide Semiconductor) on said silicon substrate to fabricate said CMOS device, wherein said NMOS has an NMOS drain current passing therethrough and said PMOS has a PMOS drain current passing therethrough on said silicon substrate, and an angle between a direction of said NMOS drain current and a direction of said PMOS drain current is ranged from 30° to 90°; and
providing a stress source for applying a strain on said NMOS and said PMOS, wherein the direction of said strain on both said NMOS and said PMOS is identical.

2. The method according to claim 1, wherein said direction of said NMOS drain current and said direction of said PMOS drain current are further perpendicular to each other.

3. The method according to claim 1, wherein said silicon substrate has an orientation of crystallization of {100}.

4. The method according to claim 1, wherein said direction of said NMOS drain current and said direction of said PMOS drain current are both in a plane having an orientation in <110>.

5. The method according to claim 1, wherein said direction of said NMOS drain current and said direction of said PMOS drain current are both in a plane having an orientation in <100>.

6. The method according to claim 1, wherein said silicon substrate further has one of P-type doping and N-type doping.

7. The method according to claim 1, wherein said strain is one of a tensile strain and a compressive strain.

8. The method according to claim 1, wherein said stress source comprises one selected from a group consisting of a high-tensile dielectric of nitrides, a high-compressive dielectric of nitrides, an STI (Shallow Trench Isolation), a strained-silicon layer, a hydrogen ion implantation and an externally mechanical stress source.

9. The method according to claim 1, wherein a plurality of said CMOS devices are fabricated on said silicon substrate.

10. A method for arranging a layout of a CMOS (Complementary Metal-Oxide Semiconductor) device, comprising the following steps:
providing a silicon substrate;
providing a stress source for applying a strain on said silicon substrate; and
forming an NMOS (N-type Metal-Oxide Semiconductor) and a PMOS (P-type Metal-Oxide Semiconductor) on said silicon substrate to fabricate said CMOS device, wherein said NMOS has an NMOS drain current passing therethrough and said PMOS has a PMOS drain current passing therethrough on said silicon substrate, and an angle between a direction of said NMOS drain current and a direction of said PMOS drain current is ranged from 30° to 90°.

11. The method according to claim 10, wherein said direction of said NMOS drain current and said direction of said PMOS drain current are further perpendicular to each other.

12. The method according to claim 10, wherein said silicon substrate has an orientation of crystallization of {100}.

13. The method according to claim 10, wherein said direction of said NMOS drain current and said direction of said PMOS drain current are both in a plane having an orientation in <110>.

14. The method according to claim 10, wherein said direction of said NMOS drain current and said direction of said PMOS drain current are both in a plane having an orientation in <100>.

15. The method according to claim 10, wherein said silicon substrate further has one of P-type doping and N-type doping.

16. The method according to claim 10, wherein said strain is one of a tensile strain and a compressive strain.

17. The method according to claim 10, wherein said stress source comprises one selected from a group consisting of a high-tensile dielectric of nitrides, a high-compressive dielectric of nitrides, an STI (Shallow Trench Isolation), a strained-silicon layer, a hydrogen ion implantation and an externally mechanical stress source.

18. The method according to claim 10, wherein a plurality of said CMOS devices are fabricated on said silicon substrate.

19. A CMOS device having a layout formed by the method of claim 1.
